(19) United States
(12) Patent Application Publication
(10) Pub. No.: US 2025/0218721 A1
(43) Pub. Date: Jul. 3, 2025

(54) SCANNING ELECTRON MICROSCOPE DEVICE

(71) Applicant: Samsung Electronics Co., Ltd., Suwon-si (KR)

(72) Inventors: Jinwoo Lee, Suwon-si (KR); Bumjoo Lee, Suwon-si (KR); Suyoung Lee, Suwon-si (KR); Jongcheon Sun, Suwon-si (KR); Hyeongcheol Lee, Suwon-si (KR)

(21) Appl. No.: 18/775,073

(22) Filed: Jul. 17, 2024

(30) Foreign Application Priority Data
Dec. 27, 2023 (KR) 10-2023-0193628
Mar. 4, 2024 (KR) 10-2024-0030498

(51) Int. Cl. H01J 37/28; H01J 37/244; H01J 37/26

(52) U.S. Cl. CPC H01J 37/28; H01J 37/244; H01J 37/265; H01J 2237/24495

(57) ABSTRACT

A scanning electron microscope device includes an electron beam source emitting a plurality of electron beams travelling to an object mounted on a stage along a plurality of different travel paths, a plurality of detectors into which a plurality of signal beams emitted from the object by the plurality of electron beams are respectively incident, and a controller determining modulation characteristics of each of the plurality of electron beams and the number of the plurality of electron beams. The controller controls the electron beam source and the plurality of detectors so that two or more signal beams are incident on each of the plurality of detectors. The controller separates an individual signal corresponding to each of the two or more signal beams from an output signal of each of the plurality of detectors, and generates an image of a target area of the object emitting the plurality of signal beams.

### CROSS-REFERENCE TO RELATED APPLICATION(S)

This application claims the benefit of priority under 35 U.S.C. § 119 of Korean Patent Application No. 10-2023-0193628, filed on Dec. 27, 2023, and Korean Patent Application No. 10-2024-0030498, filed on Mar. 4, 2024, in the Korean Intellectual Property Office, the entire disclosures of both of which are incorporated herein by reference for all purposes.

### BACKGROUND

The present inventive concept relates to a scanning electron microscope device.

In devices using electron beams, such as scanning electron microscope devices and the like, it is necessary to accurately irradiate the electron beam to an object to be analyzed and/or to be processed. The electron beam emitted from an electron beam source passes through a condenser lens, or the like, in which it is formed into an electromagnetic field, and enters the target area of the object. A signal beam emitted from the target area by an electron beam may be detected by a detector to generate an image of the target area. Recently, research into multi-beam scanning electron microscope devices performing measurements using two or more electron beams has been actively undertaken to improve the throughput of measurement work using scanning electron microscope devices.

### SUMMARY

Example embodiments provide a scanning electron microscope device in which throughput may be improved and simultaneously reliability of measurement work may be implemented, and which may be implemented in a miniaturized size, by detecting signal beams with a smaller number of detectors than the number of electron beams incident on an object.

According to example embodiments, a scanning electron microscope device includes an electron beam source configured to emit a plurality of electron beams travelling, along a plurality of different travel paths, to an object mounted on a stage, a plurality of detectors into which a plurality of signal beams emitted from the object by the plurality of electron beams are respectively incident, and a controller configured to determine modulation characteristics of each of the plurality of electron beams and the number of the plurality of electron beams. The controller is configured to control the electron beam source and the plurality of detectors so that two or more signal beams among the plurality of signal beams are incident on each of the plurality of detectors. The controller is configured to separate an individual signal corresponding to each of the two or more signal beams from an output signal of each of the plurality of detectors, and generate an image of a target area of the object emitting the plurality of signal beams.

According to example embodiments, a scanning electron microscope device includes a stage on which an object is disposed, an electron beam source configured to generate a plurality of electron beams and irradiate the plurality of electron beams to a plurality of target areas defined in different positions on the object, a plurality of detectors into which a plurality of signal beams emitted from the plurality of target areas are incident, and a controller configured to generate an image for each of the plurality of target areas using an output signal from each of the plurality of detectors. The number of the plurality of electron beams is greater than the number of the plurality of detectors.

According to example embodiments, a scanning electron microscope device includes

a stage on which an object is disposed, an electron beam source configured to generate a plurality of electron beams and irradiate the plurality of electron beams to a plurality of target areas defined in different positions on the object, a plurality of detectors into which a plurality of signal beams emitted from the plurality of target areas are incident, and a controller configured to generate an image for each of the plurality of target areas using an output signal from each of the plurality of detectors. The controller is configured to control the electron beam source so that a first electron beam irradiated to a first target area of the plurality of target areas and a second electron beam irradiated to a second target area of the plurality of target areas have an orthogonal relationship with each other. A first signal beam emitted from the first target area by the first electron beam, and a second signal beam emitted from the second target area by the second electron beam are incident on a first detector among the plurality of detectors.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram including a simplified illustration of a scanning electron microscope device according to example embodiments;

FIG. 2 is a diagram including a simplified illustration of a scanning electron microscope device according to example embodiments;

FIG. 3 is a flowchart illustrating the operation of a scanning electron microscope device according to example embodiments;

FIG. 4 is a diagram illustrating the operation of a scanning electron microscope device according to example embodiments;

FIG. 5 is a diagram illustrating the operation of a scanning electron microscope device according to example embodiments;

FIGS. 6A to 6D are diagrams illustrating electron beams incident on an object in the scanning electron microscope device according to an example embodiment illustrated in FIG.

FIG. 7 is a diagram illustrating a signal beam incident on a detector in the scanning electron microscope device according to an example embodiment illustrated in FIG. 5; FIGS. 8A to 8D are diagrams illustrating electron beams incident on an object in the scanning electron microscope device according to an example embodiment illustrated in FIG. 5;

FIG. 9 is a diagram illustrating a signal beam incident on a detector in the scanning electron microscope device according to an example embodiment illustrated in FIG. 5;

FIG. 10 is a diagram illustrating the operation of a scanning electron microscope device according to example embodiments;

FIGS. 11A and 11B are diagrams illustrating electron beams incident on an object in the scanning electron microscope device according to an example embodiment illustrated in FIG. 10;

FIGS. 12A and 12B are diagrams illustrating a signal beam incident on a detector in the scanning electron microscope device according to an example embodiment illustrated in FIG. 10;

FIG. 13 is a diagram illustrating the operation of a scanning electron microscope device according to example embodiments;

FIGS. 14A to 14D are diagrams illustrating electron beams incident on an object in the scanning electron microscope device according to an example embodiment illustrated in FIG. 13; and

FIGS. 15 and 16 are diagrams illustrating a signal beam incident on a detector in the scanning electron microscope device according to an example embodiment illustrated in FIG. 13.

### DETAILED DESCRIPTION

Hereinafter, example embodiments will be described with reference to the accompanying drawings. Like reference characters refer to like elements throughout. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The figures and their corresponding descriptions are not intended to be mutually exclusive from other figures or descriptions of the disclosure, unless the context so indicates. Therefore, certain aspects from certain figures may be the same as certain features in other figures, and/or certain figures may be different representations or different portions of a particular exemplary embodiment.

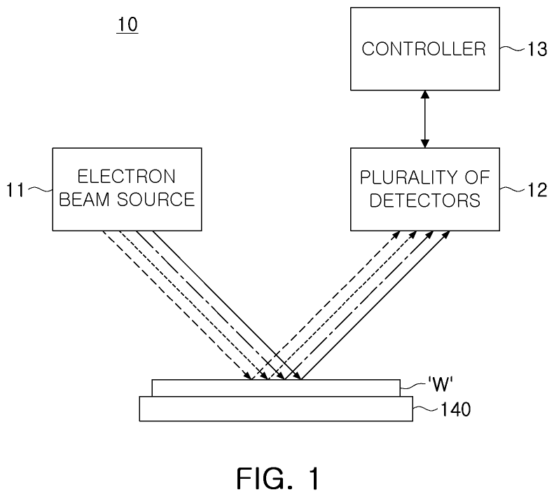

FIG. 1 is a diagram including a simplified illustration of a scanning electron microscope device according to example embodiments.

Referring to FIG. 1, a scanning electron microscope device 10 according to an example embodiment may include an electron beam source 11, a plurality of detectors 12, a controller 13, and a stage 14. An object to be measured using the scanning electron microscope device 10 is disposed on the stage 14. For example, the object may be a wafer W.

The electron beam source 11 emits an electron beam and may include lenses that control the path of the electron beam and accelerate and focus the electron beam. For example, the electron beam source 11 may include an electron gun, and the electron gun may generate electrons by heating a filament made of tungsten or the like, and apply a voltage to accelerate the electrons to generate an electron beam.

When an electron beam is incident on an object such as a wafer W, a signal beam may be emitted from the object. For example, a signal beam emitted from an object may include secondary electrons (SE), back scattered electrons (BSE), X-rays, visible light, and cathode fluorescence.

Each of the plurality of detectors 12 is installed to receive a signal beam emitted from an object, and may detect the signal beam and transmit the same to the controller 13. The controller 13 may control the electron beam source 11 so that the electron beam is incident on the object to the target area where measurement work is to be performed. Additionally, the controller 13 may control the plurality of detectors 12 so that a signal beam emitted by an electron beam in the target area is incident on at least one of the plurality of detectors 12.

When the plurality of detectors 12 detects a signal beam emitted from the target area, the controller 13 may generate an image of the target area using the detection result. For example, semiconductor devices including a gate structure and an active region are formed on an object such as a wafer W, and the critical dimension of the semiconductor devices may be measured by irradiating an electron beam to the target area where the semiconductor device is formed.

In example embodiments, as illustrated in FIG. 1, the electron beam source 11 may simultaneously irradiate two or more electron beams to an object. Electron beams may be respectively irradiated to different target areas defined on the object along different travel paths. For example, each of the different travel paths may be a path from the electron beam source 11 to a different target area of the object. Signal beams may be emitted by electron beams in each of the target areas included in the object. Accordingly, the throughput of the scanning electron microscope device 10 may be improved by simultaneously detecting signal beams emitted from different target areas by the plurality of detectors 12.

In addition, in example embodiments, the controller 13 may control the electron beam source 11 and/or the plurality of detectors 12 so that two or more signal beams are incident on at least one of the plurality of detectors 12. The controller 13 may separate two or more signal beams detected by one detector to generate individual signals and create an image based thereon. Accordingly, the scanning electron microscope device 10 may be implemented with fewer detectors 12 than the number of electron beams emitted from the electron beam source 11, and the scanning electron microscope device 10 may be miniaturized. In addition, by generating electron beams to separate crosstalk of signal beams that may occur between adjacent detectors among the plurality of detectors 12, the signal-to-noise ratio of the signal beam detected by each of the plurality of detectors 12 may be improved.

Although not illustrated, controller 13 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the electron beam source 11 and/or the plurality of detectors 12, and storage media or other suitable type of memory (e.g., such as, for example, programmable read-only memory (PROM), erasable programmable read-only memory (EPROM), electrically erasable programmable read-only memory (EEPROM), any type of tangible and non-transitory storage medium) where data and/or instructions can be stored. In addition, the controller 13 can include or be connected to a power source that provides an appropriate alternating current (AC) or direct current (DC) to power one or more components of the controller 13, and include a bus that allows communication among the various disclosed components of the controller 13.

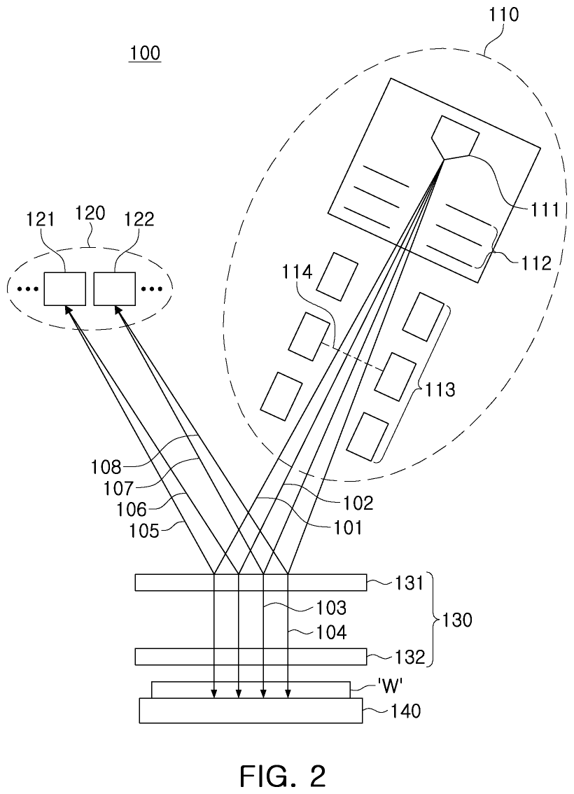

FIG. 2 is a diagram including a simplified illustration of a scanning electron microscope device according to example embodiments.

Referring to FIG. 2, a scanning electron microscope device 100 according to example embodiments may include an electron beam source 110, a plurality of detectors 120, an object optical unit 130, and a stage 140. As previously described, an object for which measurement work is to be performed is disposed on the stage 140. For example, the object may be a wafer W.

The electron beam source 110 may include an electron beam source 111 emitting an electron beam. The electron beam source 111 may be, for example, an electron gun. The electron beam emitted from the electron beam source 111 may be adjusted by the optical units 112 and 113. For example, the optical units 112 and 113 may include a condenser lens, a stigmator, a rotating lens, and the like. Additionally, the electron beam source 110 may include a plate 114 having a plurality of openings, and a plurality of electron beams 101-104 may be generated in the process of passing the electron beam emitted by the electron beam source 111 through the plurality of openings included in the plate 114.

A plurality of electron beams 101-104 may be irradiated to an object along different travel paths. An object optical unit 130 including an electrostatic deflector 131 and an objective lens unit 132 may be disposed in the path of the plurality of electron beams 101-104. For example, the objective lens unit 132 may include a plurality of optical devices that adjust each of the plurality of electron beams 101-104, and each of the plurality of optical devices may adjust beam alignment state, focal length, or the like.

Since the plurality of electron beams 101-104 are irradiated to the object along different travel paths, the plurality of electron beams 101-104 may be irradiated to target areas defined at different positions on the object. In each of the target areas, a plurality of signal beams 105-108 corresponding to a plurality of electron beams 101-104 may be emitted. The number of electron beams 101-104 may be equal to the number of signal beams 105-108.

A plurality of signal beams 105-108 may be incident on a plurality of detectors 120. In an example embodiment illustrated in FIG. 2, the first signal beam 105 and the second signal beam 106 are incident on the first detector 121, and the third signal beam 107 and the fourth signal beam 108 may be incident on the second detector 122. As such, in example embodiments, two or more of the signal beams emitted from target areas of the object by different electron beams 101-104 may be incident on one detector.

The controller of the scanning electron microscope device 100 may separate two or more signal beams incident on one detector and generate individual signals corresponding to each of the two or more signal beams. In example embodiments, to generate multiple individual signals from one detector, the controller may control the electron beam source 110 so that the signal beams incident on one detector and the corresponding electron beams have an orthogonal relationship with each other. For example, the controller may generate electron beams having an orthogonal relationship by controlling the electron beam source 110 using an orthogonal frequency division multiplexing (OFDM) method, a space time block code (STBC) method, or the like. The controller of FIG. 2 may be the same as the controller 13 of FIG. 1.

For example, a first electron beam 101 corresponding to the first signal beam 105 incident on the first detector 121, and a second electron beam 102 corresponding to the second signal beam 106 incident on the first detector 121 may have an orthogonal relationship with each other. Similarly, a third electron beam 103 corresponding to the third signal beam 107 incident on the second detector 122, and a fourth electron beam 104 corresponding to the fourth signal beam 108 incident on the second detector 122 may have an orthogonal relationship with each other.

In example embodiments, the first electron beam 101 and the second electron beam 102 may have pulse waveforms of the same frequency and different phases. By setting the time at which the first electron beam 101 is irradiated to the object in one cycle and the time at which the second electron beam 102 is irradiated to the object differently, the first electron beam 101 and the second electron beam 102 having an orthogonal relationship to each other may be generated. The controller may separate the first individual signal corresponding to the first signal beam 105 and the second individual signal corresponding to the second signal beam 106 from the signal output by the first detector 121.

Additionally, depending on the embodiment, the electron beams 101-104 corresponding to the signal beams 105-108 incident on the first detector 121 and the second detector 122 adjacent to each other may have an orthogonal relationship with each other. One of the electron beams 101-104 may have an orthogonal relationship to the others of the electron beams 101-104, and for example, the first electron beam 101 has an orthogonal relationship with the second to fourth electron beams 102-104, and the fourth electron beam 104 may have an orthogonal relationship with the first to third electron beams 101-103.

Crosstalk may occur between the first detector 121 and the second detector 122 that are physically close to each other, where the signal beams 105-108 affect each other. For example, a portion of the first signal beam 105 and the second signal beam 106 are incident on the second detector 122, and parts of the third signal beam 107 and the fourth signal beam 108 may be incident on the first detector 121. In this case, the first individual signal corresponding to the first signal beam 105 and the second individual signal corresponding to the second signal beam 106 may not be accurately generated from the output signal of the first detector 121, and likewise, the third individual signal corresponding to the third signal beam 107 and the fourth individual signal corresponding to the fourth signal beam 108 may not be accurately generated from the output signal of the second detector 122.

To significantly reduce the effect of crosstalk occurring between the first detector 121 and the second detector 122, the controller may control the electron beam source 110 so that the electron beams 101-104 have an orthogonal relationship to each other. Since the electron beams 101-104 have an orthogonal relationship to each other, the controller generates first and second individual signals corresponding to the first and second signal beams 105 and 106 in the output signal of the first detector 121. Meanwhile, the influence of the third and fourth signal beams 107 and 108 introduced into the first detector 121 due to crosstalk may be separated from the first and second individual signals. Likewise, the controller may extract third and fourth individual signals corresponding to the third and fourth signal beams 107 and 108, by excluding the influence of the first and second signal beams 105 and 106 from the output signal of the second detector 122.

In this manner, in example embodiments, a plurality of electron beams 101 to 104 are simultaneously generated to perform measurement work on an object, so that measurement work using the scanning electron microscope device 100 may be performed quickly and efficiently. Additionally, the scanning electron microscope device 100 may be implemented with fewer detectors 121-122 than the number of electron beams 101-104, and the detectors 121-122 may be arranged at high density, allowing the scanning electron microscope device 100 to be miniaturized.

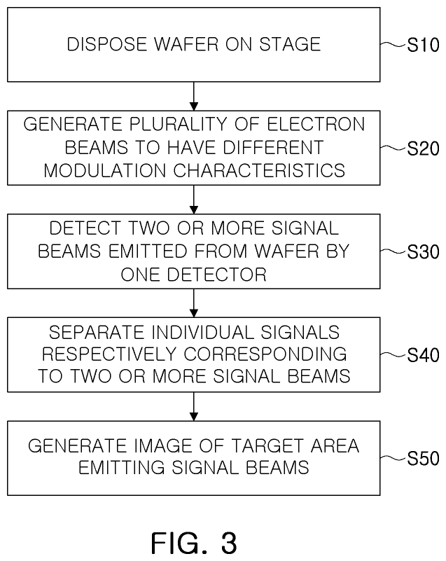

FIG. 3 is a flowchart illustrating the operation of a scanning electron microscope device according to example embodiments.

Referring to FIG. 3, the operation of the scanning electron microscope device according to example embodiments may begin by placing a wafer on the stage (S10). A wafer (e.g., wafer W) may be an object disposed on a stage (e.g., stage 14 or stage 140) for which measurement is to be performed using a scanning electron microscope device (e.g., scanning electron microscope device 10 or scanning electron microscope device 100). However, the object of measurement work is not limited to wafers, and various other objects may be put on the stage depending on the embodiment.

When a wafer is disposed on the stage, a plurality of electron beams with different modulation characteristics may be generated (S20). For example, the electron beam source (e.g., electron beam source 11 or electron beam source 111) may generate at least some of the plurality of electron beams (e.g., plurality of electron beams 101-104) to have an orthogonal relationship with each other. A plurality of electron beams are simultaneously emitted and incident on a plurality of target areas defined at different positions on the wafer, and a signal beam (e.g., signal beams 105-108) may be emitted from each of the target areas.

Signal beams emitted from the wafer may be illuminated by a plurality of detectors (e.g., plurality of detectors 12 or plurality of detectors 120). In an example embodiment of the invention, more than one of the signal beams may be directed to one detector. Accordingly, one detector may detect two or more signal beams emitted from the wafer (S30).

The controller (e.g., controller 13) may receive output signals from each of the plurality of detectors. As previously described in operation S30, for a detector in which two or more signal beams emitted from two or more target areas are irradiated, the controller may perform the task of separating individual signals corresponding to each signal beam (S40). To separate individual signals corresponding to each signal beam in operation S40, the controller may control the scanning electron microscope device so that two or more signal beams generated by two or more electron beams generated to have an orthogonal relationship with each other are incident on one detector in operation S20.

Thereafter, the controller may generate images of each target area using individual signals corresponding to each signal beam (S50). As such, in example embodiments, a plurality of electron beams may be simultaneously emitted and images of each of a plurality of target areas may be generated using the plurality of electron beams, thereby improving the efficiency of measurement work using a scanning electron microscope device. In addition, since one detector detects signal beams emitted from an object by some electron beams that are orthogonal to each other among a plurality of electron beams, scanning electron microscope devices may be miniaturized by reducing the number of detectors.

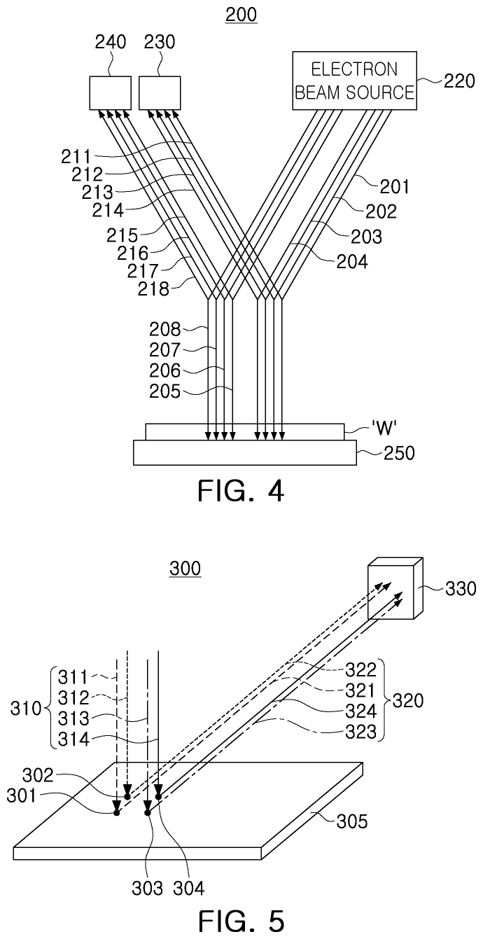

FIG. 4 is a diagram illustrating the operation of a scanning electron microscope device according to example embodiments.

Referring to FIG. 4, a scanning electron microscope device 200 according to example embodiments may include an electron beam source 220, a first detector 230, a second detector 240, and a stage 250. The electron beam source 220 may generate a plurality of electron beams 201 to 208 and irradiate them to an object such as a wafer W mounted on the stage 250.

In an example embodiment illustrated in FIG. 4, first to eighth electron beams 201-208 may be generated and irradiated to the wafer W. The first to eighth electron beams 201-208 may be irradiated to target areas defined in different positions on the wafer W. In the target areas, signal beams 211-218 may be emitted in response to the first to eighth electron beams 201-208.

Each of the signal beams 211-218 emitted from target areas of the wafer W may be incident on the first detector 230 or the second detector 240. For example, as illustrated in FIG. 4, the first to fourth signal beams 211-214 are incident on the first detector 230, and the fifth to eighth signal beams 215-218 may be incident on the second detector 240.

The first to fourth electron beams 201-204 incident on target areas emitting the first to fourth signal beams 211-214 may be generated to have an orthogonal relationship with each other. Accordingly, the first to fourth signal beams 211 to 214 incident on the first detector 230 may also have an orthogonal relationship with each other. Based on the modulation characteristics of each of the first to fourth electron beams 201-204, the controller may extract first to fourth individual signals corresponding to the first to fourth signal beams 211-214 from the output signal of the first detector 230.

Similarly, the fifth to fifth electron beams 205-208 incident on target areas emitting the fifth to eighth signal beams 215-218 may be generated to have an orthogonal relationship with each other. The fifth to eighth signal beams 215-218 incident on the second detector 240 may also have an orthogonal relationship with each other. Based on the modulation characteristics of each of the fifth to eighth electron beams 205-208, the controller may extract fifth to eighth individual signals corresponding to the fifth to eighth signal beams 215-218 from the output signal of the second detector 240.

FIG. 5 is a diagram illustrating the operation of a scanning electron microscope device according to example embodiments.

Referring to FIG. 5, in the scanning electron microscope device 300 according to example embodiments, a plurality of electron beams 311-314 (310) may be generated and irradiated to the object 305. A plurality of target areas 301 to 304 are defined in the object 305, and the plurality of target areas 301 to 304 may be defined in different locations. The object 305 may be, for example, a wafer W. Although not illustrated in FIG. 5, the scanning electron microscope device 300 may include an electron beam source (e.g., electron beam source 11 or electron beam source 111) that generates and emits the plurality of electron beams 311-314 and a controller (e.g., controller 13) that receives output signals from the detector 330.

In an example embodiment illustrated in FIG. 5, a plurality of electron beams 310 may be generated to have different modulation characteristics. For example, some of the plurality of electron beams 310 may have different frequencies. For example, a first electron beam of the plurality of electron beams 310 may be generated at a first frequency, a second electron beam of the plurality of electron beams 310 may be generated at a second frequency different from the first frequency, and the first frequency may be twice the second frequency. Additionally, in example embodiments, some of the plurality of electron beams 310 may have the same frequency and different phases.

A plurality of signal beams 321-324 (320) may be emitted from the plurality of target areas 301-304 to which the plurality of electron beams 310 are irradiated. The characteristics of each of the signal beams 320 emitted from the plurality of target areas 301-304 may be determined by the plurality of electron beams 310. In example embodiments, the plurality of electron beams 310 may be generated to have an orthogonal relationship with each other, and thus the plurality of signal beams 320 may also have an orthogonal relationship with each other.

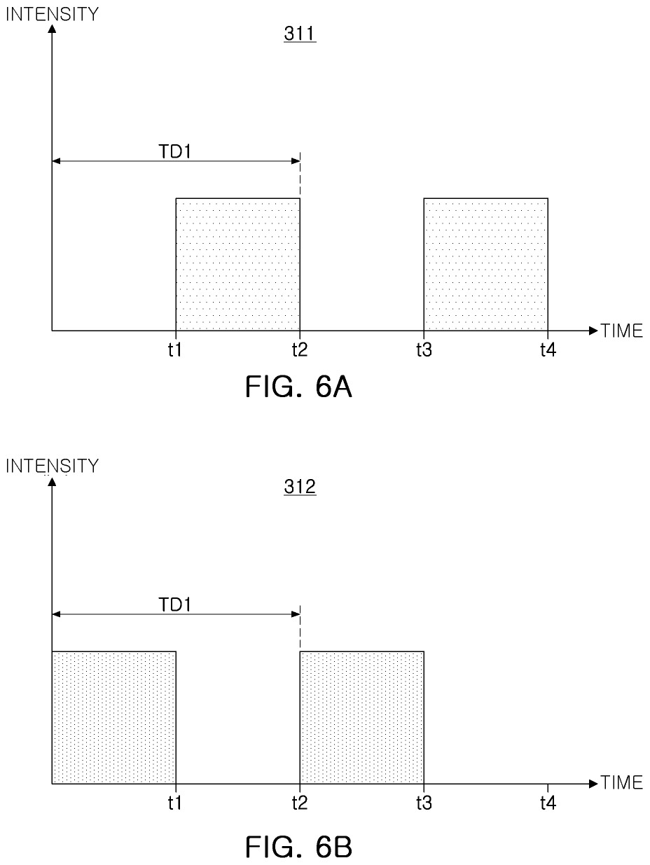

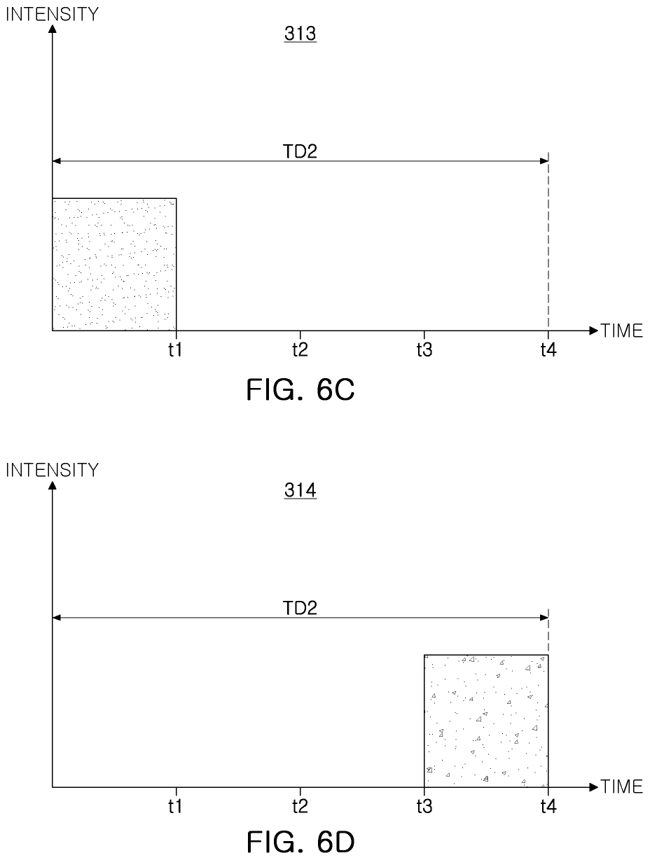

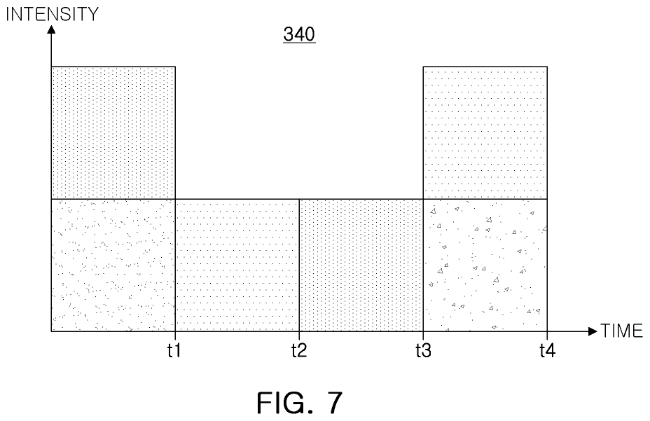

A plurality of signal beams 320 may be incident on one detector 330. Accordingly, the output signal output by the detector 330 may include individual signals corresponding to the plurality of signal beams 320. However, since the plurality of signal beams 320 have an orthogonal relationship with each other, the controller of the scanning electron microscope device 300 may extract individual signals corresponding to the plurality of signal beams 320 from the output signal of the detector 330. Hereinafter, the operation of the scanning electron microscope device 300 will be described in more detail with reference to FIGS. 6A to 6D and FIG. 7.

FIGS. 6A to 6D are diagrams illustrating electron beams incident on an object in the scanning electron microscope device according to an example embodiment illustrated in FIG. 5. Meanwhile, FIG. 7 is a diagram illustrating a signal beam incident on a detector in a scanning electron microscope device according to an example embodiment illustrated in FIG. 5.

FIG. 6A may be a diagram illustrating a pulse waveform of the first electron beam 311 emitted from an electron beam source included in the scanning electron microscope device 300. Referring to FIG. 6A, the first electron beam 311 may be generated and emitted as a pulse having a first period TD1. Accordingly, the first signal beam emitted from the first target area 301 to which the first electron beam 311 is irradiated may also have a pulse waveform similar to that of the first electron beam 311.

FIG. 6B may be a diagram illustrating a pulse waveform of the second electron beam 312 emitted from an electron beam source included in the scanning electron microscope device 300. Referring to FIG. 6B, like the first electron beam 311, the second electron beam 312 may be generated and emitted as a pulse having a first period TD1. Accordingly, the second signal beam emitted from the second target area 302 to which the second electron beam 312 is irradiated may also have a pulse waveform similar to that of the second electron beam 312.

Referring to FIGS. 6A and 6B, while the first electron beam 311 and the second electron beam 312 are generated as pulse waveforms with the same period, they may have different phases. The second electron beam 312 is not emitted during the time that the first electron beam 311 is emitted within the first period TD1, and conversely, the first electron beam 311 may not be emitted during the time during which the second electron beam 312 is emitted within the first period TD1. Accordingly, the first electron beam 311 and the second electron beam 312 may have an orthogonal relationship with each other.

FIG. 6C may be a diagram illustrating the pulse waveform of the third electron beam 313 emitted from the electron beam source included in the scanning electron microscope device 300. Referring to FIG. 6C, the third electron beam 313 may be generated and emitted as a pulse having a second period TD2 longer than the first period TD1. The third signal beam emitted from the third target area 303 to which the third electron beam 313 is irradiated may have a pulse waveform similar to that of the third electron beam 313.

Meanwhile, FIG. 6D may be a diagram illustrating the pulse waveform of the fourth electron beam 314 emitted from the electron beam source included in the scanning electron microscope device 300. Referring to FIG. 6D, the fourth electron beam 314 may be generated and emitted as a pulse having the long second period TD2 like the third electron beam 313.

However, the fourth electron beam 314 may have a different phase from the third electron beam 313. The fourth signal beam emitted from the fourth target area 304 to which the fourth electron beam 314 is irradiated may have a pulse waveform similar to that of the fourth electron beam 314.

Referring to FIGS. 6C and 6D, the third electron beam 313 and the fourth electron beam 314 are generated as pulse waveforms with the same period, but may have different phases. The fourth electron beam 314 is not emitted during the time the third electron beam 313 is emitted within the second period TD2, and conversely, the third electron beam 313 may not be emitted during the time during which the fourth electron beam 314 is emitted within the second period TD2. Accordingly, the third electron beam 313 and the fourth electron beam 314 may have an orthogonal relationship with each other.

As described with reference to FIG. 5, the first to fourth signal beams 321 to 324 emitted from the first to fourth target areas 301 to 304 may be incident on one detector 330. FIG. 7 may be a graph including a simplified illustration of the output signal 340 of the detector 330.

As previously described with reference to FIGS. 6A to 6D, the first to fourth electron beams 311-314 are generated with different pulse waveforms and irradiated to the first to fourth target areas 311-314, and accordingly, the first to fourth signal beams 321-324 may also be generated with different pulse waveforms. The controller that receives the output signal 340 from the detector 330 may extract individual signals corresponding to each of the first to fourth signal beams 321-324 from the output signal 340, with reference to the pulse waveforms of the first to fourth electron beams 311-314 emitted from the electron beam source.

Referring to FIGS. 6A to 6D, during the time between the first time point t1 and the second time point t2, the electron beam source may emit only the first electron beam 311. Additionally, during the time between the second time point t2 and the third time point t3, the electron beam source may emit only the second electron beam 312. Therefore, the controller that receives the output signal 340 as illustrated in FIG. 7 may determine that the output signal 340 at the time between the first time point t1 and the second time point t2 includes only the first signal beam 321. Additionally, the controller may determine that the output signal 340 at the time between the second time point t2 and the third time point t3 includes only the second signal beam 322.

The controller may determine the intensity of the first signal beam 321 using the intensity of the output signal 340 at the time between the first time point t1 and the second time point t2, and determine the intensity of the second signal beam 322 using the intensity of the output signal 340 at the time between the second time point t2 and the third time point t3. At a time before the first time t1, the electron beam source may emit the second electron beam 312 and the third electron beam 313 together. Therefore, the controller may determine the intensity of the third signal beam 323 by subtracting the output signal 340 at the time between the second time point t2 and the third time point t3 from the output signal 340 at the time before the first time point t1.

Meanwhile, during the time between the third time point t3 and the fourth time point t4, the electron beam source may simultaneously emit the first electron beam 311 and the fourth electron beam 314. Therefore, the controller may determine intensity of the fourth signal beam 324 by subtracting the output signal 340 at the time between the first time point t1 and the second time point t2 from the output signal 340 at the time between the third time point t3 and the fourth time point t4.

As such, in example embodiments, electron beams 311-314 generated to have different modulation characteristics are simultaneously irradiated to the target areas 301-304, and signal beams 321-324 emitted from the target areas 301-304 may be detected by one detector 330. Therefore, the scanning electron microscope device 300 may be miniaturized by reducing the number of detectors 330, and the throughput of the scanning electron microscope device 300 may be improved by simultaneously performing measurement work on a plurality of target areas 301-304.

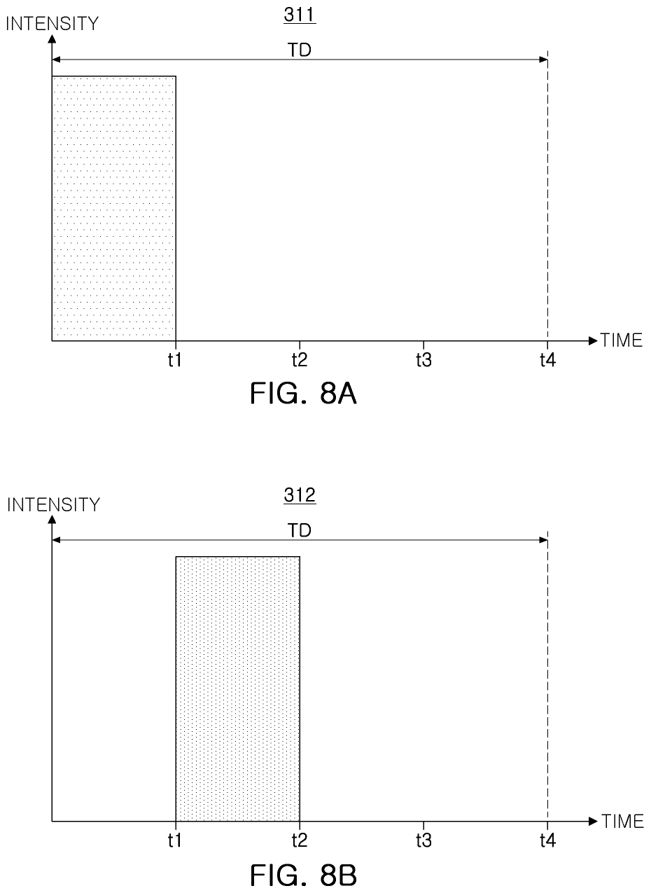

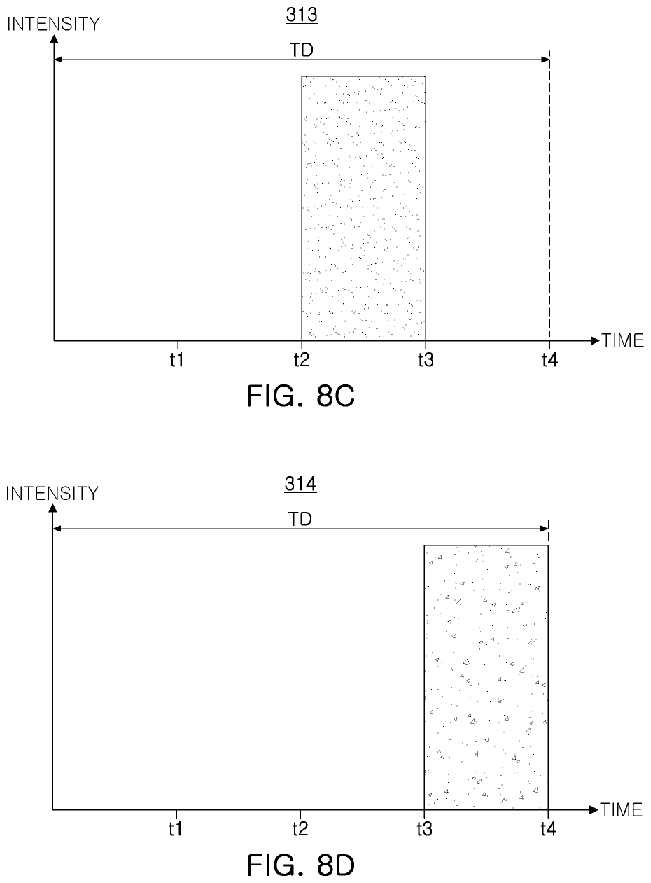

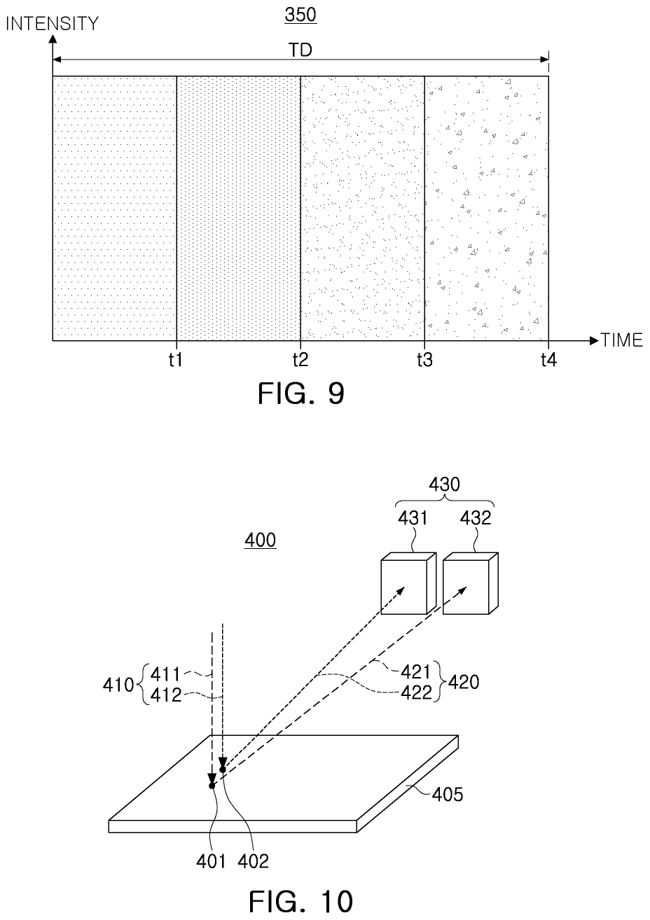

FIGS. 8A to 8D are diagrams illustrating electron beams incident on an object in the scanning electron microscope device according to an example embodiment illustrated in FIG. 5. Meanwhile, FIG. 9 is a diagram illustrating the signal beam incident on the detector in the scanning electron microscope device according to an example embodiment illustrated in FIG. 5.

FIGS. 8A to 8D are diagrams illustrating pulse waveforms of first to fourth electron beams 311 to 314 emitted from an electron beam source included in the scanning electron microscope device 300. In the embodiment described with reference to FIGS. 8A to 8D, each of the first to fourth electron beams 311 to 314 may be generated as a pulse having the same period TD. Additionally, the first to fourth electron beams 311-314 may have different phases.

First, referring to FIG. 8A, the first electron beam 311 may be emitted during a time before the first time point t1. The second electron beam 312 is emitted during the time between the first time point t1 and the second time point t2 as illustrated in FIG. 8B, and the third electron beam 313 may be emitted during the time between the second time point t2 and the third time point t3, as illustrated in FIG. 8C. The fourth electron beam 314 may be emitted during the time between the third time point t3 and the fourth time point t4, as illustrated in FIG. 8D.

Referring to FIGS. 8A to 8D, the first to fourth electron beams 311-314 may be generated as pulses with the same frequency and different phases. The emission times of the first to fourth electron beams 311 to 314 within one period TD may not overlap with each other. Accordingly, the first to fourth electron beams 311-314 have an orthogonal relationship with each other, and the first to fourth signal beams 321-324 emitted from the first to fourth target areas 301-304 to which the first to fourth electron beams 311-314 are irradiated may also have an orthogonal relationship with each other.

FIG. 9 may be a graph including a simplified illustration of the output signal 350 of the detector 330 into which the first to fourth signal beams 321-324 emitted from the first to fourth target areas 301-304 are incident. As previously described with reference to FIGS. 8A to 8D, the first to fourth electron beams 311-314 are generated with different pulse waveforms and irradiated to the first to fourth target areas 301-304, and accordingly, the first to fourth signal beams 321-324 may also be generated with different pulse waveforms and incident on the detector 330. The controller that receives the output signal 350 from the detector 330 may extract individual signals corresponding to each of the first to fourth signal beams 321-324 from the output signal 350 by referring to the pulse waveform of the first to fourth electron beams 311-314 emitted from the electron beam source.

For example, the controller may determine the first signal beam 321 from the output signal 350 at a time before the first time point t1, and may determine a second signal beam 322 using the output signal 350 at a time between the first time point t1 and the second time point t2. In addition, the controller determines the third signal beam 323 using the output signal 350 at the time between the second time point t2 and the third time point t3, and may determine a fourth signal beam 324 is generated using the output signal 350 at a time between the third time point t3 and the fourth time point t4.

In this manner, the controller may extract first to fourth signal beams 321-324 from the output signal 350 generated by one detector 330, with reference to the modulation characteristics of the first to fourth electron beams 311-314 whose emission times from the electron beam source do not overlap. Therefore, the scanning electron microscope device 300 may be miniaturized by reducing the number of detectors 330, and the throughput of the scanning electron microscope device 300 may be improved by simultaneously performing measurement work on a plurality of target areas 301-304.

FIG. 10 is a diagram illustrating the operation of a scanning electron microscope device according to example embodiments.

Referring to FIG. 10, in the scanning electron microscope device 400 according to example embodiments, a plurality of electron beams 411 and 412 (410) may be generated and irradiated to the object 405. The object 405 may be, for example, a wafer W. Although not illustrated in FIG. 10, the scanning electron microscope device 400 may include an electron beam source (e.g., electron beam source 11 or electron beam source 111) that generates and emits the plurality of electron beams 410 and a controller (e.g., controller 13) that receives output signals from the detectors 430.

The plurality of electron beams 410 may be irradiated to a plurality of target areas 401 and 402 defined in different positions on the object 405.

In an example embodiment illustrated in FIG. 10, a plurality of electron beams 410 may be generated to have different modulation characteristics. For example, some of the plurality of electron beams 410 may have different frequencies. For example, a first electron beam of the plurality of electron beams 410 may be generated at a first frequency, a second electron beam of the plurality of electron beams 410 may be generated at a second frequency different from the first frequency, and the first frequency may be twice the second frequency. Additionally, in example embodiments, some of the plurality of electron beams 410 may have the same frequency and different phases. A plurality of electron beams 410 may be generated to have an orthogonal relationship with each other.

A plurality of signal beams 421 and 422 (420) may be emitted from the plurality of target areas 401 and 402 to which the plurality of electron beams 410 are irradiated. The characteristics of each of the signal beams 420 emitted from the plurality of target areas 401 and 402 may be determined by the plurality of electron beams 410. In example embodiments, like the plurality of electron beams 410 having an orthogonal relationship with each other, the plurality of signal beams 420 may also have an orthogonal relationship with each other.

A plurality of signal beams 420 may be incident on different detectors 431 and 432 (430). In example embodiments, the first signal beam 421 may be incident on the first detector 431, and the second signal beam 422 may be incident on the second detector 432. The controller may identify the first signal beam 421 from the output signal of the first detector 431 and the second signal beam 422 from the second detector 432.

To miniaturize the scanning electron microscope device 400, the detectors 430 may be disposed as close to each other as possible. Due to the narrow spacing between the detectors 430, part of the first signal beam 421 may be incident on the second detector 432, and part of the second signal beam 422 may be incident on the first detector 431. A portion of the first signal beam 421 incident on the second detector 432 acts as noise to the second signal beam 422, and some of the second signal beam 422 incident on the first detector 431 may act as noise to the first signal beam 421. Accordingly, the precision of measurement work using the scanning electron microscope device 400 may be reduced.

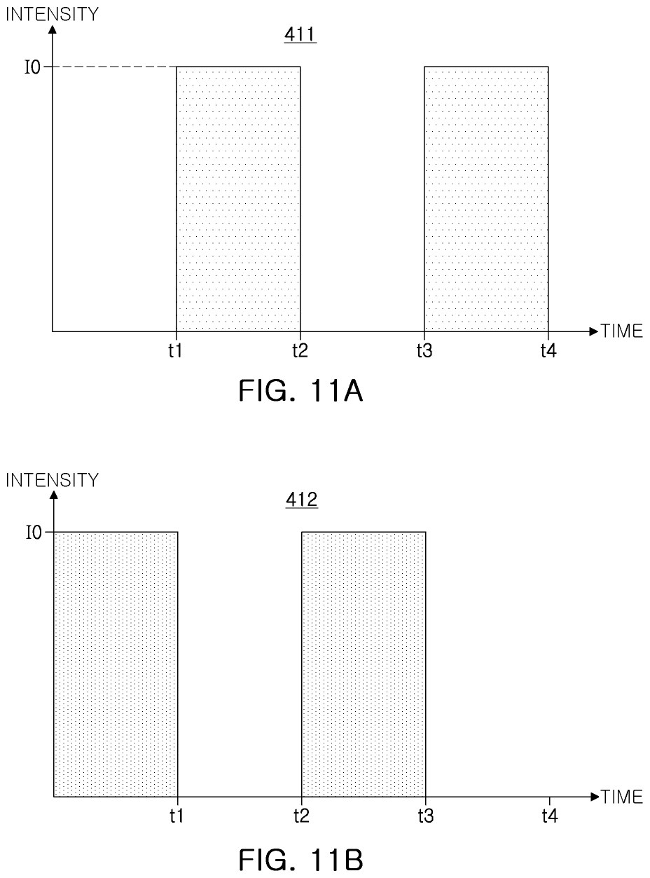

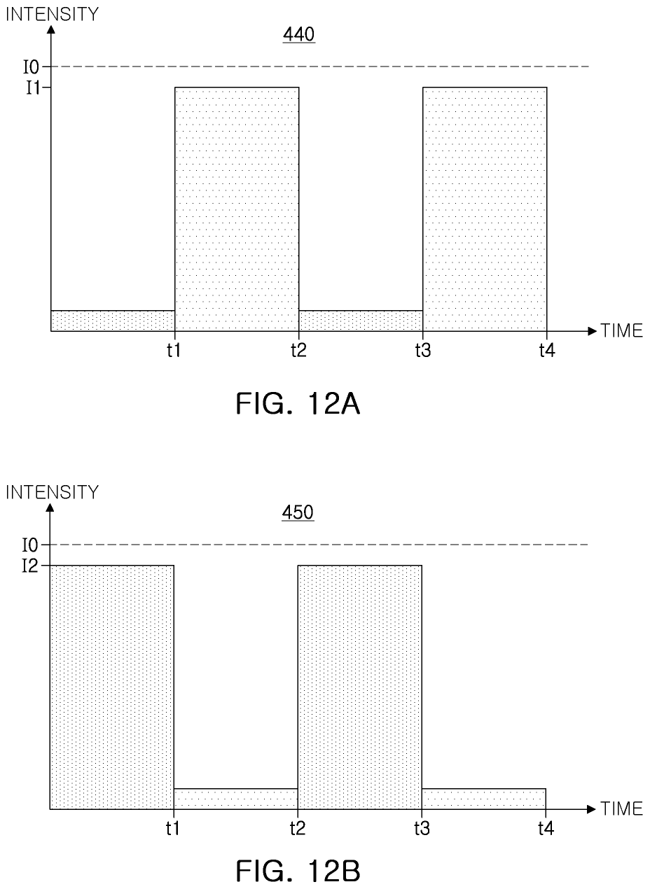

In example embodiments, the controller of the scanning electron microscope device 400 may remove the component of the second signal beam 422 from the output signal of the first detector 431 with reference to the modulation characteristics of the electron beams 410, and may remove components of the first signal beam 421 in the output signal of the second detector 432. Accordingly, the precision of the measurement work may be secured while the detectors 430 are disposed close together. Hereinafter, the operation of the scanning electron microscope device 400 will be described in more detail with reference to FIGS. 11A and 11B and FIGS. 12A and 12B.

FIGS. 11A and 11B are diagrams illustrating electron beams incident on an object in the scanning electron microscope device according to an example embodiment illustrated in FIG. 10. Meanwhile, FIGS. 12A and 12B are diagrams illustrating the signal beam incident on the detector in the scanning electron microscope device according to an example embodiment illustrated in FIG. 10.

FIG. 11A may be a diagram illustrating the pulse waveform of the first electron beam 411 emitted from an electron beam source included in the scanning electron microscope device 400. Referring to FIG. 11A, the first electron beam 411 may be generated and emitted as a pulse having a predetermined period. The first signal beam emitted from the first target area 401 to which the first electron beam 411 is radiated may have a pulse waveform similar to that of the first electron beam 411.

FIG. 11B may be a diagram illustrating a pulse waveform of the second electron beam 412 emitted from an electron beam source included in the scanning electron microscope device 400. Referring to FIG. 11B, the second electron beam 412 may be generated and emitted as a pulse having the same period as the first electron beam 411. The second signal beam emitted from the second target area 402 to which the second electron beam 412 is irradiated may have a pulse waveform similar to that of the second electron beam 412.

Referring to FIGS. 11A and 11B, the first electron beam 411 and the second electron beam 412 are generated as pulse waveforms with the same period, but may have different phases. The second electron beam 412 is not emitted during the time the first electron beam 411 is emitted within one cycle, and conversely, the first electron beam 411 may not be emitted during the time during which the second electron beam 412 is emitted within one cycle. Accordingly, the first electron beam 411 and the second electron beam 412 may have an orthogonal relationship with each other. Each of the first electron beam 411 and the second electron beam 412 may be emitted at a reference intensity I0 for a portion of time within one cycle.

FIG. 12A may be a diagram illustrating a first output signal 440 of the first detector 431, and FIG. 12B may be a diagram illustrating a second output signal 450 of the second detector 432. As previously described with reference to FIG. 10, a portion of the second signal beam 422 may be incident on the first detector 431, and a portion of the first signal beam 421 may be incident on the second detector 432.

Referring to FIG. 12A, the first signal beam 421 included in the first output signal 440 may have the same phase as the first electron beam 411 and may have a first intensity I1. Meanwhile, the first output signal 440 includes a noise signal, and the noise signal may be generated by a portion of the second signal beam 422 incident on the first detector 431. Accordingly, the noise signal may have the same phase as the second electron beam 412.

The controller of the scanning electron microscope device 400 may distinguish between a first individual signal corresponding to the first signal beam 421 and a noise signal from the first output signal 440. With reference to the modulation characteristics of the first electron beam 411 and the second electron beam 412, since the first electron beam 411 and the second electron beam 412 are generated at different phases, the controller may extract a first individual signal corresponding to the first signal beam 421 from the first output signal 440 with reference to the phase of the first electron beam 411, and may identify noise signal with reference to the phase of the second electron beam 412.

Referring to FIG. 12B, the second signal beam 422 included in the second output signal 450 may have the same phase as the second electron beam 412 and have a second intensity I2. Meanwhile, the second output signal 450 includes a noise signal, and the noise signal may be generated by a portion of the first signal beam 421 incident on the second detector 432. Therefore, the noise signal may have the same phase as the first electron beam 411.

The controller of the scanning electron microscope device 400 may distinguish a second individual signal corresponding to the second signal beam 422 from the second output signal 450 and a noise signal, by referring to the modulation characteristics of the first electron beam 411 and the second electron beam 412. Since the first electron beam 411 and the second electron beam 412 are generated at different phases, the controller identifies the noise signal by referring to the phase of the first electron beam 411 in the first output signal 440, and may extract a second individual signal corresponding to the second signal beam 422 with reference to the phase of the second electron beam 412.

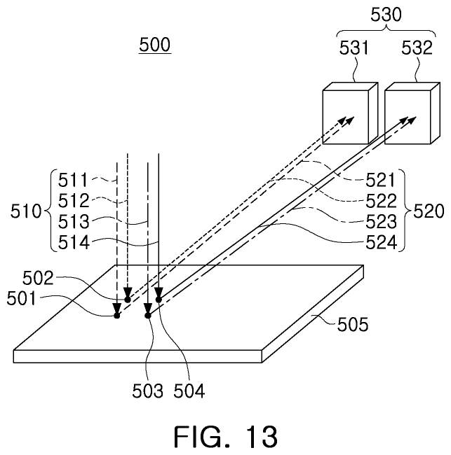

FIG. 13 is a diagram illustrating the operation of a scanning electron microscope device according to example embodiments.

Referring to FIG. 13, in the scanning electron microscope device 500 according to example embodiments, a plurality of electron beams 511-514 (510) may be generated and irradiated to the object 505. The plurality of electron beams 510 may be irradiated to a plurality of target areas 501-504 defined in different positions on the object 505. The object 505 may be, for example, a wafer W. Although not illustrated in FIG. 13, the scanning electron microscope device 500 may include an electron beam source (e.g., electron beam source 11 or electron beam source 111) that generates and emits the plurality of electron beams 510 and a controller (e.g., controller 13) that receives output signals from the detectors 530.

In an example embodiment illustrated in FIG. 13, a plurality of electron beams 510 may be generated to have different modulation characteristics. For example, some of the plurality of electron beams 510 may have different frequencies. For example, a first electron beam of the plurality of electron beams 510 may be generated at a first frequency, a second electron beam of the plurality of electron beams 510 may be generated at a second frequency different from the first frequency, and the first frequency may be twice the second frequency. Some of the plurality of electron beams 510 may have the same frequency and different phases. A plurality of electron beams 510 may be generated to have an orthogonal relationship with each other.

A plurality of signal beams 521-524 (520) may be emitted from the plurality of target areas 501-504 to which the plurality of electron beams 510 are irradiated. The characteristics of each of the plurality of signal beams 520 may be determined by the plurality of electron beams 510. In example embodiments, when the plurality of electron beams 510 have an orthogonal relationship with each other, the plurality of signal beams 520 may also have an orthogonal relationship with each other.

A plurality of signal beams 520 may be incident on different detectors 531 and 532 (530). For example, the first signal beam 521 and the second signal beam 522 may be incident on the first detector 531, and the third signal beam 523 and the fourth signal beam 524 may be incident on the second detector 532. The controller may identify the first signal beam 521 and the second signal beam 522 from the output signal of the first detector 531, and identify the third signal beam 523 and the fourth signal beam 524 from the output signal of the second detector 532.

As previously described with reference to FIG. 10, the detectors 530 may be disposed as close to each other as possible to miniaturize the scanning electron microscope device 500. Accordingly, signal interference may occur between adjacent detectors 530. For example, at least a portion of the first signal beam 521 and the second signal beam 522 may be incident on the second detector 532. Additionally, at least a portion of the third signal beam 523 and the fourth signal beam 524 may be incident on the first detector 531.

Part of the first signal beam 521 and/or part of the second signal beam 522 incident on the second detector 532 may act as noise for the third signal beam 523 and the fourth signal beam 524. In addition, part of the third signal beam 523 and/or part of the fourth signal beam 524 incident on the first detector 531 may act as noise for the first signal beam 521 and the second signal beam 522. Accordingly, the precision of the measurement operation for the object 505 may deteriorate.

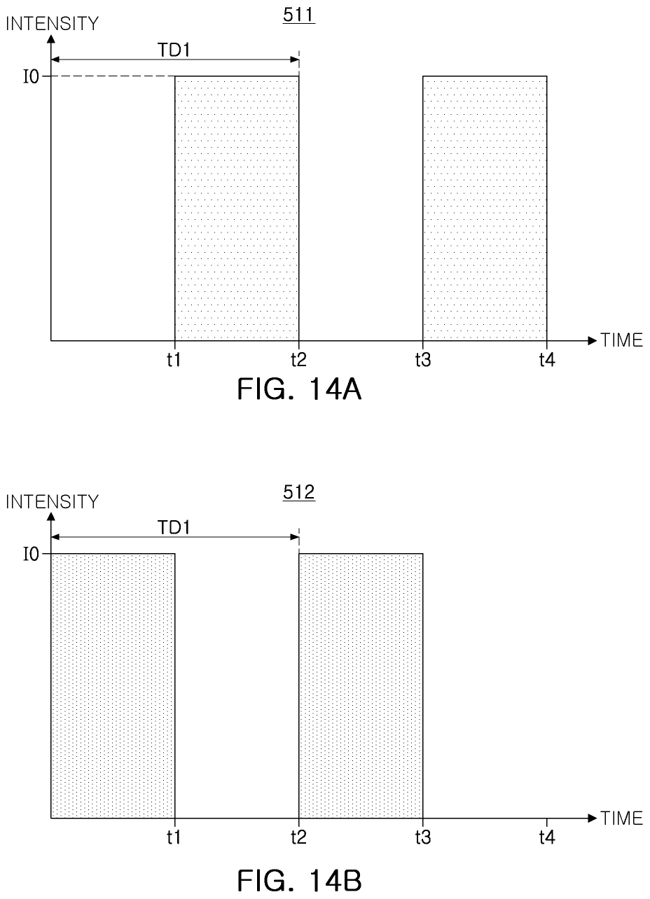

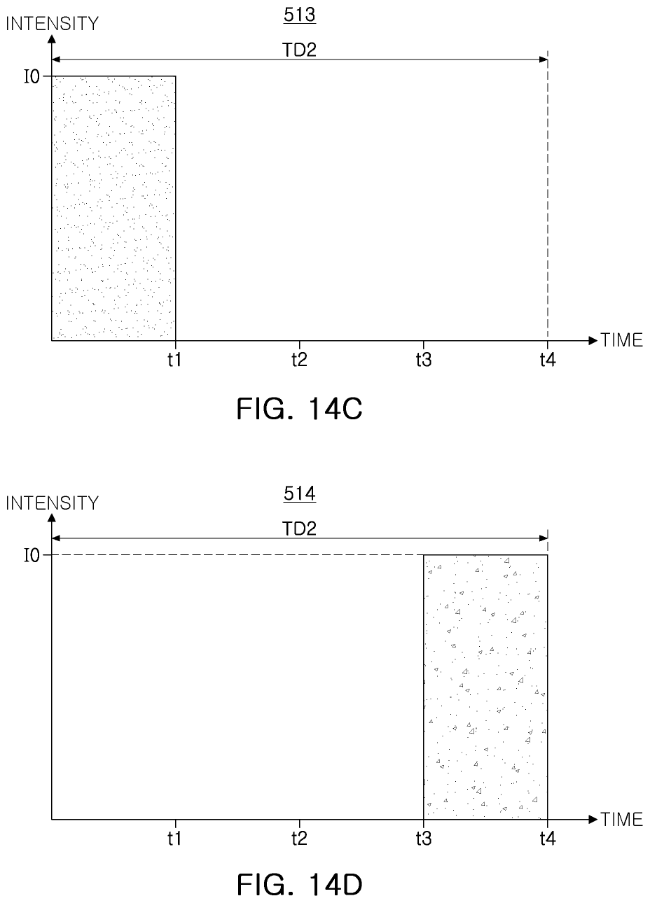

In example embodiments, with reference to the modulation characteristics of the electron beams 510, the controller of the scanning electron microscope device 500 may identify a noise signal in each of the output signals of the first detector 531 and the output signal of the second detector 532. Accordingly, the precision of the measurement work may be secured while the detectors 530 are disposed close together. Hereinafter, the operation of the scanning electron microscope device 500 will be described in more detail with reference to FIGS. 14A to 14D, 15, and 16.

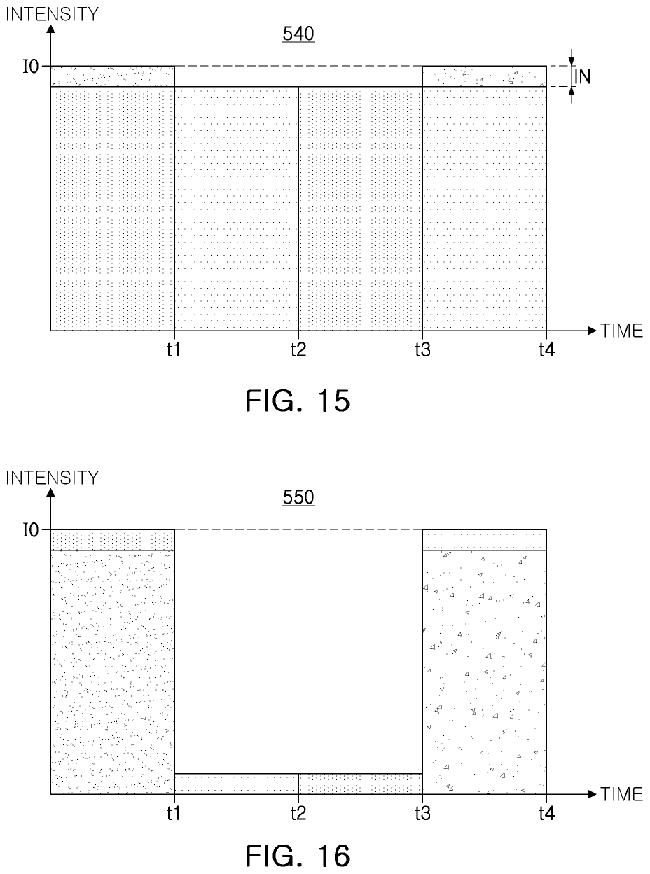

FIGS. 14A to 14D are diagrams illustrating electron beams incident on an object in the scanning electron microscope device according to an example embodiment illustrated in FIG. 13. Meanwhile, FIGS. 15 and 16 are diagrams illustrating the signal beam incident on the detector in the scanning electron microscope device according to the embodiment illustrated in FIG. 13.

FIGS. 14A to 14D may be diagrams illustrating pulse waveforms of each of the first to fourth electron beams 511 to 514 emitted from an electron beam source included in the scanning electron microscope device 500. As illustrated in FIGS. 14A to 14D, each of the first to fourth electron beams 511 to 514 may be generated with a reference intensity I0.

Referring to FIGS. 14A and 14B, each of the first electron beam 511 and the second electron beam 512 may be generated and emitted as a pulse having a first period TD1. However, the first electron beam 511 and the second electron beam 512 may have different phases. Therefore, the first electron beam 511 and the second electron beam 512 have an orthogonal relationship with each other, and the controller may distinguish the first signal beam 521 and the second signal beam 522 from the output signal of the first detector 531.

Referring to FIGS. 14C and 14D, each of the third electron beam 513 and the fourth electron beam 514 may be generated and emitted as a pulse having a second period TD2 different from the first period TD1. The third electron beam 513 and the fourth electron beam 514 have different phases, and therefore, the controller may distinguish the third signal beam 523 and the fourth signal beam 524 from the output signal of the second detector 532.

FIG. 15 may be a diagram illustrating a first output signal 540 of the first detector 531, and FIG. 16 may be a diagram illustrating a second output signal 550 of the second detector 532. As previously described with reference to FIG. 13, a portion of the third signal beam 523 and/or the fourth signal beam 524 is incident on the first detector 531, and a portion of the first signal beam 521 and/or the second signal beam 522 may be incident on the second detector 532.

Referring to FIG. 15, the first output signal 540 may include a first signal beam 521 and a second signal beam 522. Since the first signal beam 521 has the same phase as the first electron beam 511, and the second signal beam 522 has the same phase as the second electron beam 512, the controller may distinguish between a first individual signal corresponding to the first signal beam 521 and a second individual signal corresponding to the second signal beam 522 in the first output signal 540, with reference to the modulation characteristics of each of the first electron beam 511 and the second electron beam 512.

Meanwhile, the controller may identify the third signal beam 523 and the fourth signal beam 524 from the first output signal 540. With reference to the modulation characteristics of each of the third electron beam 513 and the fourth electron beam 514, for example, the controller may determine the intensity of the first signal beam 521 during the time between the first time point t1 and the second time point t2, and determine intensity of the second signal beam 522 during the time between the second time point t2 and the third time point t3.

The control department may identify noise signal caused by a portion of the third signal beam 523 incident on the first detector 531, by subtracting the first output signal 540 at the time between the second time point t2 and the third time point t3 from the first output signal 540 at the time before the first time point t1. Also, the controller may identify noise signal caused by a portion of the fourth signal beam 524 incident on the first detector 531, by subtracting the first output signal 540 at the time between the first time point t1 and the second time point t2 from the first output signal 540 at the time between the third time point t3 and the fourth time point t4. Accordingly, the controller may remove the noise signal generated when a portion of the third signal beam 523 and/or the fourth signal beam 524 flows into the first detector 531 from the first output signal 540, and thus, the precision of measurement work may be improved.

Referring to FIG. 16, the second output signal 550 may include a third signal beam 523 and a fourth signal beam 524. Since the third signal beam 523 has the same phase as the third electron beam 513, and the fourth signal beam 524 has the same phase as the fourth electron beam 514, the controller may distinguish a third individual signal corresponding to the third signal beam 523 and a fourth individual signal corresponding to the fourth signal beam 524 from the second output signal 550, with reference to the modulation characteristics of each of the third electron beam 513 and the fourth electron beam 514.

Meanwhile, the controller may identify part of the first signal beam 521 and/or part of the second signal beam 522 introduced into the second detector 532 from the second output signal 550, by referring to the modulation characteristics of each of the first electron beam 511 and the second electron beam 512. For example, the controller determines the intensity of a portion of the first signal beam 521 introduced into the second detector 532 during the time between the first time point t1 and the second time point t2, and the intensity of a portion of the second signal beam 522 introduced into the second detector 532 during the time between the second time point t2 and the third time point t3.

The controller may accurately detect third signal beam 523 by subtracting the second output signal 550 at the time between the second time point t2 and the third time point t3 from the second output signal 550 at the time before the first time point t1. Also, the controller may accurately detect the fourth signal beam 524 by subtracting the second output signal 550 at the time between the first time point t1 and the second time point t2 from the second output signal 550 at the time between the third time point t3 and the fourth time point t4. The controller may remove a noise signal generated when a portion of the first signal beam 521 and/or the second signal beam 522 flows into the second detector 532 from the second output signal 550, and thus the precision of measurement work may be improved.

As set forth above, according to example embodiments, a plurality of electron beams incident on an object along different travel paths may be generated, and two or more of signal beams emitted from the object may be incident on one detector. Electron beams corresponding to two or more signal beams incident on one detector are formed to have different modulation characteristics, and individual signals corresponding to two or more signal beams, respectively, may be separated from the signal output from one detector through signal processing. Therefore, a larger number of signal beams may be processed with a smaller number of detectors, and thus, the scanning electron microscope device may be miniaturized, and simultaneously, the throughput may be improved. Therefore, the accuracy of measurement work may be improved by reducing crosstalk between signal beams.

While example embodiments have been illustrated and described above, it will be apparent to those skilled in the art that modifications and variations could be made without departing from the scope of the present inventive concept as defined by the appended claims.

What is claimed is:

1. A scanning electron microscope device comprising:
an electron beam source configured to emit a plurality of electron beams travelling, along a plurality of different travel paths, to an object mounted on a stage;
a plurality of detectors into which a plurality of signal beams emitted from the object by the plurality of electron beams are respectively incident; and
a controller configured to determine modulation characteristics of each of the plurality of electron beams and a number of the plurality of electron beams,
wherein the controller is configured to control the electron beam source and the plurality of detectors so that two or more signal beams among the plurality of signal beams are incident on each of the plurality of detectors, and
wherein the controller is configured to separate an individual signal corresponding to each of the two or more signal beams from an output signal of each of the plurality of detectors, and generate an image of a target area of the object emitting the plurality of signal beams.

2. The scanning electron microscope device of claim 1,
wherein the electron beam source is configured to generate a first electron beam incident on a first region of the object along a first travel path, and a second electron beam incident on a second region of the object along a second travel path,
wherein a first signal beam emitted from the first region by the first electron beam and a second signal beam emitted from the second region by the second electron beam are incident on a first detector of the plurality of detectors, and
wherein the first travel path is different from the second travel path, and the first region is different from the second region.

3. The scanning electron microscope device of claim 2, wherein the first electron beam is generated at a first frequency, and the second electron beam is generated at a second frequency different from the first frequency.

4. The scanning electron microscope device of claim 2, wherein each of the first electron beam and the second electron beam is generated at a first frequency, and the first electron beam and the second electron beam have different phases.

5. The scanning electron microscope device of claim 2, wherein the first electron beam is an orthogonal signal to the second electron beam.

6. The scanning electron microscope device of claim 4,
wherein the electron beam source generates a third electron beam incident on a third region of the object along a third travel path, and a fourth electron beam incident on a fourth region of the object along a fourth travel path,
wherein a third signal beam emitted from the third region by the third electron beam and a fourth signal beam emitted from the fourth region by the fourth electron beam are incident on the first detector, and
wherein the first to fourth travel paths are different from each other, and the first to fourth regions are different from each other.

7. The scanning electron microscope device of claim 6, wherein each of the first electron beam and the second electron beam is generated at the first frequency, and each of the third electron beam and the fourth electron beam is generated at a second frequency different from the first frequency.

8. The scanning electron microscope device of claim 7, wherein the first frequency is twice the second frequency.

9. The scanning electron microscope device of claim 6, wherein each of the first to fourth electron beams is an orthogonal signal to a remainder of the first to fourth electron beams.

10. The scanning electron microscope device of claim 1,
wherein the electron beam source generates a first electron beam incident on a first region of the object along a first travel path, and a second electron beam incident on a second region of the object along a second travel path,
wherein a first signal beam emitted from the first region by the first electron beam is incident on a first detector, and a second signal beam emitted from the second region by the second electron beam is incident on a second detector adjacent to the first detector, and
wherein the controller obtains a first individual signal corresponding to the first signal beam by removing interference of the second signal beam in the first detector, and obtains a second individual signal corresponding to the second signal beam by removing interference of the first signal beam in the second detector.

11. The scanning electron microscope device of claim 10, wherein the first electron beam and the second electron beam have different phases.

12. The scanning electron microscope device of claim 10, wherein the first electron beam is an orthogonal signal to the second electron beam.

13. A scanning electron microscope device comprising:
a stage on which an object is disposed;
an electron beam source configured to generate a plurality of electron beams and irradiate the plurality of electron beams to a plurality of target areas defined in different positions on the object;
a plurality of detectors into which a plurality of signal beams emitted from the plurality of target areas are incident; and
a controller configured to generate an image for each of the plurality of target areas using an output signal from each of the plurality of detectors,
wherein a number of the plurality of electron beams is greater than a number of the plurality of detectors.

14. The scanning electron microscope device of claim 13, wherein two or more signal beams among the plurality of signal beams are incident on at least one detector among the plurality of detectors.

15. The scanning electron microscope device of claim 14, wherein the controller controls the electron beam source so that two or more electron beams irradiated to two or more target areas emitting the two or more signal beams have an orthogonal relationship with each other.

16. The scanning electron microscope device of claim 13,
wherein the plurality of detectors include a first detector and a second detector adjacent to each other, a first signal beam among the plurality of signal beams is incident on the first detector, and a second signal beam among the plurality of signal beams is incident on the second detector, and
wherein the controller controls the electron beam source so that the first signal beam and the second signal beam have an orthogonal relationship with each other.

17. The scanning electron microscope device of claim 16,
wherein the first signal beam includes a plurality of first signal beams, and the second signal beam includes a plurality of second signal beams, and
wherein the controller controls the electron beam source so that the plurality of first signal beams and the plurality of second signal beams have an orthogonal relationship with each other.

18. A scanning electron microscope device comprising:
a stage on which an object is disposed;
an electron beam source configured to generate a plurality of electron beams and irradiate the plurality of electron beams to a plurality of target areas defined in different positions on the object;
a plurality of detectors into which a plurality of signal beams emitted from the plurality of target areas are incident; and
a controller configured to generate an image for each of the plurality of target areas using an output signal from each of the plurality of detectors,
wherein the controller is configured to control the electron beam source so that a first electron beam irradiated to a first target area of the plurality of target areas and a second electron beam irradiated to a second target area of the plurality of target areas have an orthogonal relationship with each other, and
wherein a first signal beam emitted from the first target area by the first electron beam, and a second signal beam emitted from the second target area by the second electron beam are incident on a first detector among the plurality of detectors.

19. The scanning electron microscope device of claim 18,
wherein the controller is configured to control the electron beam source so that a third electron beam irradiated to a third target area among the plurality of target areas and a fourth electron beam irradiated to a fourth target area among the plurality of target areas have an orthogonal relationship with each other, and each of the third electron beam and the fourth electron beam has an orthogonal relationship with the first electron beam and the second electron beam, and
wherein a third signal beam emitted from the third target area by the third electron beam and a fourth signal beam emitted from the fourth target area by the fourth electron beam are incident on the first detector.

20. The scanning electron microscope device of claim 18,
wherein the controller is configured to control the electron beam source so that a third electron beam irradiated to a third target area among the plurality of target areas and a fourth electron beam irradiated to a fourth target area among the plurality of target areas have an orthogonal relationship with each other, and each of the third electron beam and the fourth electron beam has an orthogonal relationship with the first electron beam and the second electron beam, and
wherein a third signal beam emitted from the third target area by the third electron beam and a fourth signal beam emitted from the fourth target area by the fourth electron beam are incident on a second detector adjacent to the first detector.
